(19) United States
(12) Patent Application Publication
(10) Pub. No.: US 2004/0082138 A1
(43) Pub. Date: Apr. 29, 2004

(54) Method and preparing a mask for high energy particle bombardment

(76) Inventors: Lin Wen-Chin, Hsin-Chu (TW); Denny D. Tang, Saratuga, CA (US); Tsing-Tyan Yang, Taoyung (TW); David Jeng, Hsin-Chu (TW)

Correspondence Address: DUANE MORRIS, LLP, ATTN: WILLIAM H. MURRAY, ONE LIBERTY PLACE, 1650 MARKET STREET, PHILADELPHIA, PA, 19103-7396, US

(21) Appl. No.: 10/278,965

(22) Filed: Oct. 23, 2002

(51) Int. Cl. H01L 21/76; H01L 21/324; H01L 21/477

(52) U.S. Cl. 438/400; 438/423; 438/528; 438/798

(57) ABSTRACT

A method of forming a mask for bombardment of a semiconductor substrate with high energy particles and a mask formed thereby are provided. A patterned layer of a blocking material is formed over a mask substrate to define a high energy particle bombardment mask pattern. The blocking material has sufficient thickness in the mask pattern to substantially shield the semiconductor substrate from selected high energy particles in areas overlapped by the mask pattern when the mask is aligned over the semiconductor substrate. The mask includes a mask substrate having a patterned layer of blocking material formed thereon to define a high energy particle bombardment mask pattern. The blocking material has sufficient thickness in the mask pattern to substantially shield the semiconductor substrate from selected high energy particles in areas of the semiconductor substrate overlapped by the mask pattern when the mask is aligned over the semiconductor substrate.

### FIELD OF THE INVENTION

The present invention relates to masks and more particularly to masks for high energy particle bombardment of semiconductor wafers.

### BACKGROUND OF THE INVENTION

Aluminum plates or plates formed from other high atomic weight materials are commonly used as a mask to pattern the area of a semiconductor wafer for high energy particle implantation, such as for forming deep isolation regions in the semiconductor wafer. These plates are positioned between the particle source and the semiconductor wafer to mask the wafer. The use of such plates as masks in forming isolation regions is described in, for example, U.S. Pat. No. 6,046,109 to Liao et al, entitled “Creation of Local Semi-Insulating Regions on Semiconductor Substrates” issued Apr. 4, 2000, the entirety of which is hereby incorporated by reference herein. Patterns are formed in these masks by mechanically removing portions of the masks.

Another form of aluminum mask is described in U.S. Pat. No. 6,214,750 to Liao, entitled “Alternative Structure to SOI Using Proton Beams” issued Apr. 10, 2001, the entirety of which is also hereby incorporated by reference herein. Liao describes his mask as an aluminum “contact mask” that is formed directly on a passivation layer formed over an integrated circuit. A seed layer is deposited over the passivation layer to allow electrical continuity to an electrolyte bath for the deposition of a shielding layer. A layer of photoresist is then laid down over the seed layer. The photoresist is exposed through a suitable mask and then developed, resulting in a resist pattern that covers everywhere except where it is intended to grow and additional layer of metal. The additional layer of metal is then deposited by electroplating onto seed layer in the exposed regions, thereby forming a contact mask.

There are several drawbacks associated with the use of aluminum mask plates as described above. First, the accuracy obtainable with the mask plates is generally limited, often to within a tolerance range of ±50 μm. This range is not appropriate for newer generations of integrated circuits, which utilize ever smaller device features. In addition, the coefficient of thermal expansion of the mask generally does not match that of the bombarded semiconductor wafer. This in turn leads to alignment problems between the mask and the semiconductor wafer due to mask heating during high energy particle bombardment. Still further, there are limitations on the patterns that may be designed on the mask. For example, a closed ring-type pattern cannot be accomplished without utilizing a holder affixed to the plate for support. The mask of the '750 patent, although providing greater design flexibility, is not usable, being that it is integrally formed with the IC substrate. Further, the mask of the '750 complicates and makes more costly the fabrication process because each wafer must undergo additional deposition, lithography and etching processes.

Therefore, there remains a need for a new mask suitable for high energy particle implantation or bombardment of semiconductor wafers and method of forming the same that provides for greater flexibility in pattern design and improved tolerance ranges. Still further, there remains a need for a mask that does not suffer from alignment problems associated with mismatch in the coefficient of thermal expansion between the mask and the semiconductor wafer.

### SUMMARY OF THE INVENTION

A method of forming a mask for bombardment of a semiconductor substrate with high energy particles includes the step of forming a patterned layer of a blocking material over a mask substrate to define a high energy particle bombardment mask pattern. The blocking material has sufficient thickness in the mask pattern to substantially shield the semiconductor substrate from selected high energy particles in areas overlapped by the mask pattern when the mask is aligned over the semiconductor substrate.

A mask for bombardment of a semiconductor substrate with high energy particles is also provided and includes a mask substrate having a patterned layer of blocking material formed thereon to define a high energy particle bombardment mask pattern. The blocking material has sufficient thickness in the mask pattern to substantially shield the semiconductor substrate from selected high energy particles in areas of the semiconductor substrate overlapped by the mask pattern when the mask is aligned over the semiconductor substrate.

The method and mask allow for greater design flexibility because know lithographic fabrication techniques can be utilized to form the mask pattern. Indeed, unlimited design patterns can be obtained via the reusable mask, including closed-ring patterns not previously possible with known non-contact aluminum masks. Still further, the mask substrate material and the semiconductor substrate material can be matched such that they share the same coefficient of thermal expansion and thereby avoid misalignment problems due to heating of the mask associated with prior art aluminum masks.

The above and other features of the present invention will be better understood from the following detailed description of the preferred embodiments of the invention that is provided in connection with the accompanying drawings.

### BRIEF DESCRIPTION OF THE DRAWINGS

The accompanying drawings illustrate preferred embodiments of the invention, as well as other information pertinent to the disclosure, in which:

FIGS. 1A-1C each include a top plan view and cross-sectional view of a mask and illustrate exemplary methods of forming a mask structure; and

FIG. 2 is an illustration of an exemplary fabrication system using a mask of the present invention.

### DETAILED DESCRIPTION

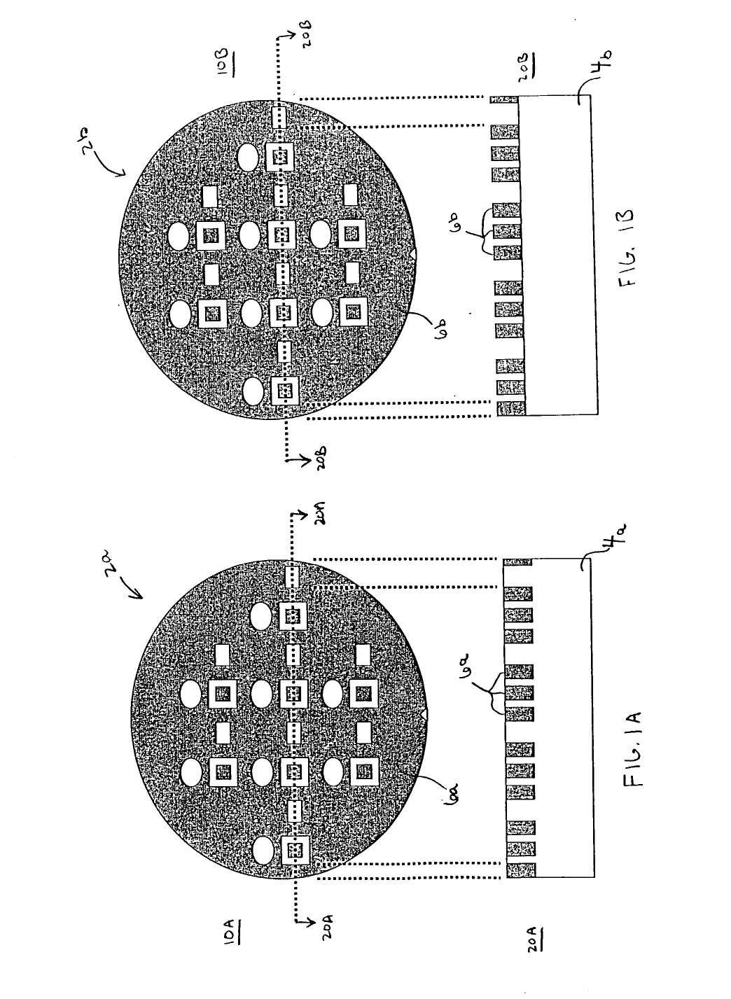

Referring first to FIGS. 1A-1C, a new mask for high energy particle implantation is described, along with a method of fabricating the same. FIG. 1A includes a top plan view 10A of a mask 2a. Also shown in FIG. 1A is a cross-sectional view 20A of the mask 2a taken along lines 20A. Mask 2a includes a mask substrate 4a, which is preferably a wafer formed from a flat glass panel or a semiconductor wafer such as a silicon wafer.

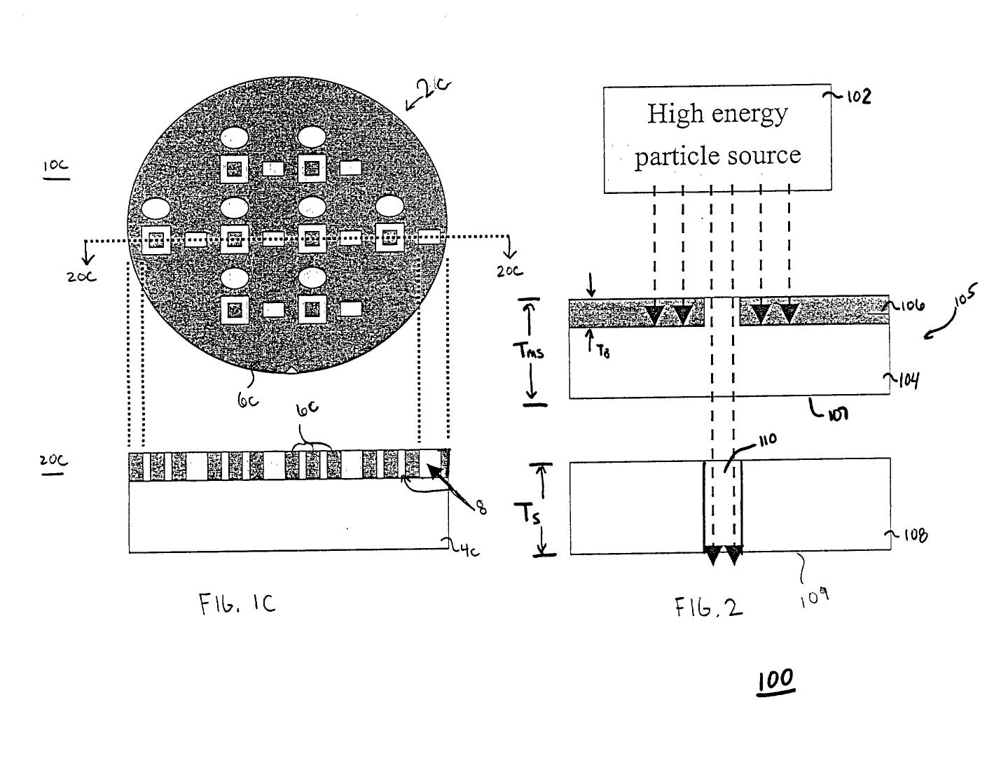

The mask 2a includes a patterned layer of blocking material 6a. The blocking material 6a is patterned to define the mask pattern for high energy particle bombardment/implantation of a semiconductor substrate having an integrated circuit formed thereon (not shown) described below in connection with FIG. 2. The particular mask pattern illustrated is provided for illustrative purposes only and does not form a part of the present invention.

The blocking material 6a preferably has a shielding power that is greater than that of the substrate 4a. The blocking material and mask substrate preferably are formed from materials that have a short half-life after use in the implantation process. It is preferred that there is a relatively fast decay of the radiation in the mask after bombardment. The daughter nuclei should decrease to less than 3% after 24 hours. This provides for safer handling by operators. Examples of exemplary blocking materials include silicon, iron, germanium, gallium, tungsten, platinum, tantalum, gold, aluminum and titanium. Thickness considerations for the patterned layer of blocking material 6a and the substrate 4a are described below in connection with FIG. 2. In one exemplary embodiment, mask substrate 4a is a glass or silicon wafer and the patterned layer of blocking material 6a is tungsten.

Conventional integrated circuit (IC) fabrication processes can be utilized to form the patterned layer of blocking material 6a on the substrate 4a, thereby providing an unlimited range of possible designs. Referring again to FIG. 1A, the desired mask pattern is etched into the substrate 4a using lithography and etch processes familiar to those of ordinary skill. The blocking material 6a is then deposited over the substrate 4a to fill the mask pattern etched into the substrate 4a. The deposited layer is then polished, such as by chemical mechanical polishing (CMP) techniques, to the top surface of the substrate 4a to provide a planar surface and uniform thickness as shown in FIG. 1A.

An alternative method of fabricating a mask 2b is illustrate via FIG. 1B. Like FIG. 1A, FIG. 1B shows a top plan view 10B of a mask 2b having the same mask pattern as the mask 2a of FIG. 1A. Also shown in FIG. 1B is a cross-sectional view 20B of the mask 2b taken along lines 20B. The mask 2b includes a mask substrate 4b having a patterned layer of blocking material 6b formed thereon. In the fabrication method illustrated by the mask 2b of FIG. 1B, a blanket layer of blocking material 6b is first deposited over the substrate 4b. Then, lithography and etching are employed to pattern the blanket layer into the desired patterned layer of blocking material 6b, i.e., a photoresist layer is deposited over the blocking material, exposed through a suitable mask and developed, and the undeveloped resist and underlying blocking material are etched.

Still further, other techniques may be employed to provide a patterned layer of blocking material, and the mask and fabrications technique should not be limited to any particular method of forming the patterned layer of blocking material. For example, as illustrated via the mask 2c of FIG. 1C, a damascene process generally utilized for copper electroplating may be employed. A blanket layer of a material 8 is deposited over the substrate 4c. The material 8 is then patterned via lithography and etching to form the mask pattern therein. The blocking material 6c is then deposited over the material 8 and in the etched regions and subsequently polished to provide a planar surface and consistent thickness as shown in FIG. 1C. Material 8 is preferably not a blocking material, i.e., it substantially passes high energy particles when compared with the selected deposited blocking material 6c. Examples of appropriate material 8 include SiO₂, SiN, SION, Si, which are readily available in the conventional IC fabrication process.

In still another alternative embodiment, the so called “lift-off process” for metal patterning may be utilized to form the patterned layer of blocking material. A photoresist is deposited over a mask substrate and patterned prior to depositing the blocking material. The blocking material is then deposited over the substrate and patterned photoresist layer. The photoresist layer is then stripped along with the blocking material that covers the photoresist, leaving the patterned layer of blocking material.

In this manner, highly accurate mask designs can be accomplished by utilizing know lithography and fabrication techniques. Still further, there is no limitation on the design for the mask pattern. Design considerations for an exemplary mask are described hereafter.

The appropriate thicknesses for the substrate and the patterned layer of blocking material of the mask described herein depend on the particle energy and the radiation extinction coefficient of the selected materials. As can be seen from the chart below illustrating a few exemplary blocking materials, the penetration depth of the protons (in micrometers) is material and energy (in Mega-electron volts) dependent.

| Energy | | | | | |
|---|---|---|---|---|---|
| of H+ | Si | Al | Ni | W | Au |
| 1 MeV | 15.7 μm | 14.3 μm | 6.1 μm | 5.3 μm | 5.4 μm |
| 5 MeV | 213.7 μm | 189.8 μm | 72.5 μm | 57.0 μm | 57.9 μm |
| 15 MeV | 1400.0 μm | 1300.0 μm | 452.1 μm | 309.0 μm | 330.0 μm |
| 30 MeV | 4800.0 μm | 4300.0 μm | 1500.0 μm | 978.5 μm | 1000.0 μm |

The above information can be used to design a mask 105 for use in an integrated circuit fabrication system 100 of FIG. 2 for creating semi-insulating regions 110 in a semiconductor substrate 108. If complete isolation between regions is desired, the system should be designed such that the high energy particles pass completely through the bombarded substrate or as nearly through as possible to the bottom surface 109 of the substrate 108. There are a number of situations where the isolating region needs to go to a significant depth below the top surface of the substrate 108, in some cases all the way through to the bottom surface 109. Examples include reduction of substrate noise coupling, realization of high Q inductors on silicon mixed mode ICs, reduction of transmission line loss for high frequency ICs, and the separation of different types of devices such as analog from digital or bipolar from CMOS.

The system includes a source 102 of high energy particles, such as a cyclotron. The high energy particles may be protons or deutrons, for example. Electromagnetic radiation, such as X-rays or gamma rays, may also be utilized. A mask 105 is aligned between the source 102 and a semiconductor substrate 108. The mask may be suspended above the semiconductor substrate 108 or be directly placed on the semiconductor substrate 108, as long as it does not scratch the semiconductor substrate 108. The mask 105 is shown as the type fabricated using the method described in connection with FIG. 1A, but this is for illustrative purposes only, and one of ordinary skill should realize that these design considerations apply equally to other masks fabricated as described above. The semiconductor substrate 108 may include an integrated circuit formed thereon and include both analog and digital circuitry. As is shown in FIG. 2, mask 106 includes a mask substrate 104 having a patterned layer of blocking material 105 formed thereon. The substrate 108 is shielded from high energy particles from source 102 in areas of the substrate 108 that are overlapped by the patterned blocking material 106. Areas not shielded by the blocking material 106 are bombarded by the high energy particles to form semi-insulating region 110.

Using available information such as that shown in the above table, appropriate thicknesses for the materials of mask 105 and energy levels for the particles from particle source 102 may be determined. Assume, for example, that approximately 400 μm of penetration depth is desired in a silicon semiconductor substrate 108 to form semi-insulating region 110. This 400 μm depth may be the thickness T_{S} of the substrate 108 if complete isolation between regions is desired or required or some depth less than the thickness T_{S} of the substrate 108. Using information from the above chart, it can be estimated that a 175 μm thick (T_{B}) layer of tungsten is an effective mask for 10 MeV proton particles. These values can be calculated from a penetration depth formula familiar to those of ordinary skill. The same high energy particles having an energy of 10 MeV penetrate to around 725 μm in silicon. Assuming that the mask substrate 104 is silicon, it should have a thickness T_{MS} of approximately 325 μm to ensure a penetration depth of approximately 400 μm in semiconductor substrate 108 in non-masked regions, i.e., the combined thickness of the substrates 104 and 108 equal the 725 μm penetration depth of the 10 MeV particles in silicon. In summary, the energy of the particle implantation or bombardment from source 102 and thicknesses of the mask substrate 104 and blocking material 106 should be selected such that particles cross the mask 105 in open, non-blocking material areas and penetrate a desired depth into the semiconductor substrate 108, and that the particles stop somewhere in the mask 105 (either in blocking material 106 or mask substrate 104) for areas shielded by the blocking material 106.

The thickness T_{B} of the patterned layer of blocking material 106 can certainly be controlled during its formation through process parameters associated with deposition and etching processes familiar to those of ordinary skill. The thickness of the mask substrate 104 is preferably kept as practically small as possible, so as to reduce the energy of the particles required to pass through the mask substrate in non-masked areas. An exemplary silicon substrate, for example, preferably has a thickness that is between 0 and 1000 μm. The thickness of the mask substrate 104 may be controlled even after formation of the patterned layer of blocking material 106 by polishing or grinding the rear surface 107 of the mask substrate such that the mask substrate obtains the desired thickness T_{MS}.

In one exemplary embodiment of a mask 105 and system 100, the mask substrate 104 is formed from the same material as the semiconductor substrate 108. In one exemplary embodiment, both substrates 104,108 are silicon. In this manner, the mask substrate 104 and the semiconductor substrate 108 have the same coefficient of thermal expansion. The substrates 104, 108, therefore, expand the same amount during implantation, thereby reducing the possibility of misalignment often found with prior art aluminum masks between the implantation pattern embodied in the mask 105 and the semiconductor substrate 108.

It is known that semi-insulating regions produced by proton bombardment are unstable over long periods of time if maintained at temperatures in excess of about 400° C. Therefore, the semi-insulating regions are preferably formed after the manufacture of the integrated circuit is completed on the substrate 108. Once this is the case, the process and system described above may be implemented to produce the semi-insulating regions. Note that although the embodiment described above is given in terms of a silicon substrate 108, the present system and method are not limited to this semiconductor material and would still be applicable if other semiconductors such as germanium, gallium arsenide, silicon-germanium, indium phosphide, or gallium nitride were selected.

It is contemplated that the entire implantation pattern for a semiconductor substrate 108 need not be formed on a single mask. Rather, smaller masks patterns may be fabricated on a wafer that is then cut into smaller individual masks. Specific areas of the semiconductor substrate can be exposed to high energy particles through the smaller mask or masks separately in a shot by shot fashion. This feature provides added flexibility. For example, a plurality of different mask patterns can be formed on a wafer and then cut for later usage.

In still another embodiment, a mask may be formed from the mask substrate itself. For example, a patterned photoresist layer may be formed over a silicon mask substrate in the pattern of the desired mask design. The silicon mask substrate is then etched to form relatively thin or open regions designed to substantially pass the high energy particles. The original thickness of the silicon mask substrate is selected to have a thickness sufficient to act as a blocking material for the selected high energy particles. Referring to the example of the silicon-tungsten mask described above in connection with FIG. 2 as illustrative, the original thickness of the silicon mask substrate can be selected to be equal to or greater than the penetration depth of the 10 MeV protons, i.e., approximately 725 μm. The mask pattern is then etched into the silicon mask substrate to a depth of approximately equal to or greater than 400 μm, leaving 325 μm thick or less of silicon in the etched areas. In this manner, the high energy particles passing through these etched regions can penetrate the desired 400 μm into the target IC silicon substrate in areas overlapped by the etched regions and the high energy particles incident on the thicker 725 μm non-etched portion of the mask substrate are stopped by the mask substrate from reaching the target IC silicon substrate.

Although the invention has been described in terms of exemplary embodiments, it is not limited thereto. Rather, the appended claims should be construed broadly to include other variants and embodiments of the invention that may be made by those skilled in the art without departing from the scope and range of equivalents of the invention

What is claimed is:

1. A method of forming a mask for bombardment of a semiconductor substrate with high energy particles, comprising the steps of:
forming a patterned layer of a blocking material over a mask substrate to define a high energy particle bombardment mask pattern, said blocking material having sufficient thickness in said mask pattern to substantially shield said semiconductor substrate from selected high energy particles in areas overlapped by said mask pattern when said mask is aligned over said semiconductor substrate.

2. The method of claim 1, wherein said mask substrate is a glass or a semiconductor wafer.

3. The method of claim 2, wherein said blocking material is selected from the group consisting of silicon, iron, germanium, gallium, tungsten, platinum, tantalum, aluminum, gold and titanium.

4. The method of claim 1, wherein said forming step includes the following steps:
lithographically defining said mask pattern on said mask substrate;
etching said mask pattern in said mask substrate; and
depositing said blocking material in said mask pattern.

5. The method of claim 4, wherein said depositing step includes the steps of depositing said blocking material over a top surface of said mask substrate and polishing said blocking material to said top surface.

6. The method of claim 1, wherein said forming step includes the following steps:
depositing a layer of said blocking material on said substrate;
patterning and forming a photoresist layer over said blocking material to define said mask pattern; and
etching said blocking material in exposed areas to form said patterned layer.

7. The method of claim 1, wherein said patterned layer is formed using a damascene process.

8. The method of claim 1, wherein said forming step includes the following steps:
patterning and forming a photoresist layer over said mask substrate to define said mask pattern;
depositing a layer of said blocking material over said substrate, wherein said blocking material is deposited in said mask pattern and over said photoresist layer; and
removing said photoresist layer, thereby leaving said patterned layer of blocking material.

9. The method of claim 1, further comprising the step of polishing a bottom surface of said mask substrate so that said substrate has a thickness of less than approximately 1000 μm.

10. The method of claim 1, wherein said mask substrate is formed from a first material different from said blocking material, said blocking material having greater shielding power relative to said selected high energy particles than said first material.

11. A mask for bombardment of a semiconductor substrate with high energy particles comprising a mask substrate having a patterned layer of blocking material formed thereon to define a high energy particle bombardment mask pattern, said blocking material having sufficient thickness in said mask pattern to substantially shield said semiconductor substrate from selected high energy particles in areas of said semiconductor substrate overlapped by said mask pattern when said mask is aligned over said semiconductor substrate.

12. The mask of claim 11, wherein said mask substrate is a glass substrate or a semiconductor substrate.

13. The mask of claim 12, wherein said blocking material is selected from the group consisting of silicon, iron, germanium, gallium, tungsten, platinum, tantalum, aluminum, gold and titanium.

14. The mask of claim 11, wherein said mask substrate is formed from a first material different from said blocking material, said blocking material having greater shielding power relative to said selected high energy particles than said first material.

15. The mask of claim 12, wherein said mask substrate is silicon and said blocking material is tungsten.

16. A method of forming semi-insulating regions in a semiconductor substrate, comprising the steps of:
aligning a mask over said semiconductor substrate, said mask including a mask substrate having a patterned layer of blocking material formed thereon to define a high energy particle bombardment mask pattern, said blocking material having sufficient thickness in patterned areas to substantially shield said semiconductor substrate from selected high energy particles in areas of said semiconductor substrate overlapped by said patterned areas; and
irradiating said semiconductor substrate with said selected high energy particles through said mask to form semi-insulating regions in said semiconductor substrate.

17. The method of claim 16, wherein said mask substrate is a glass substrate or a semiconductor substrate.

18. The method of claim 17, wherein said blocking material is selected from the group consisting of silicon, iron, germanium, gallium, tungsten, platinum, tantalum, aluminum, gold and titanium.

19. The method of claim 16, wherein said mask substrate is formed from a first material different from said blocking material, said blocking material having greater shielding power relative to selected high energy particles than said first material.

20. The method of claim 19, wherein said mask substrate is silicon and said blocking material is tungsten.

21. The method of claim 16, wherein said semiconductor substrate and said mask substrate are formed from the same material, whereby said substrates have the same coefficient of thermal expansion.

22. The method of claim 16, further comprising the step of fabricating said mask, said fabricating step including the following step:
forming said patterned layer of said blocking material over said mask substrate.

23. The method of claim 16, wherein said selected high energy particles are protons or deuterons.

24. An integrated circuit fabrication system, comprising:
a source of high energy particles for bombardment of a semiconductor substrate, whereby semi-insulating regions are formed in said semiconductor substrate; and
a mask aligned between said source and said semiconductor substrate, said mask comprising a mask substrate having a patterned layer of blocking material defining a high energy particle bombardment mask patter, said blocking material having sufficient thickness in said mask pattern to shield said semiconductor substrate from said high energy particles in areas of said semiconductor substrate overlapped by said mask pattern.

25. The system of claim 24, wherein said mask substrate is a glass substrate or a semiconductor substrate.

26. The system of claim 24, wherein said semiconductor substrate and said mask substrate are formed from the same material, whereby said substrates have the same coefficient of thermal expansion.

27. The system of claim 26, wherein said blocking material is selected from the group consisting of silicon, iron, germanium, gallium, tungsten, platinum, tantalum, aluminum, gold and titanium.

28. The system, of claim 26, wherein said mask substrate is silicon and said blocking material is tungsten.

29. The system of claim 26, wherein said mask substrate is formed from a first material different from said blocking material, said blocking material having greater shielding power relative to said high energy particles than said first material.

30. The system of claim 26, wherein said source of high energy particles is a source of protons or deuterons.

31. A method of forming a mask for bombardment of a semiconductor substrate with high energy particles, comprising the steps of:
patterning and forming a photoresist layer over a mask substrate to define a high energy particle bombardment mask pattern on a mask substrate; and
etching said mask pattern into said mask substrate, wherein said mask substrate has sufficient thickness in non-etched areas to substantially shield a semiconductor substrate from selected high energy particles in areas overlapped by said non-etched areas when said mask is aligned over said semiconductor substrate.

32. The method of claim 31, wherein said mask substrate is a silicon wafer.

33. A mask for bombardment of a semiconductor substrate with high energy particles, comprising:
a silicon mask wafer having a high energy particle mask pattern etched therein, wherein said mask wafer has sufficient thickness in non-etched areas to substantially shield a semiconductor substrate from selected high energy particles in areas overlapped by said non-etched areas when said mask is aligned over said semiconductor substrate.
